(19) United States
(12) Patent Application Publication
(10) Pub. No.: US 2008/0254588 A1
(43) Pub. Date: Oct. 16, 2008

(54) METHODS FOR FORMING TRANSISTORS WITH HIGH-K DIELECTRIC LAYERS AND TRANSISTORS FORMED THEREFROM

(75) Inventors: Harry Chuang, Austin, TX (US); Kong-Beng Thei, Pao-Shan Village (TW); Hung-Chih Tsai, Wongyuan Village (TW); M. Y. Wu, Hsinchu City (TW); Mong-Song Liang, Hsinchu (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/735,797

(22) Filed: Apr. 16, 2007

(51) Int. Cl. H01L 21/04

(52) U.S. Cl. 438/308; 257/E21.04

(57) ABSTRACT

A method for forming a semiconductor structure includes forming a gate dielectric layer over a substrate. A top surface of the gate dielectric layer is treated so as to at least partially nitridize the gate dielectric layer. The treated gate dielectric layer is thermally treated with an oxygen-containing precursor such that the at least partially nitridized gate dielectric layer has a nitrogen concentration between about 0.5 atomic percentage (at. %) and about 20 at %.

### BACKGROUND OF THE INVENTION

1. Field of the Invention

The present invention relates, most generally, to methods for forming semiconductor structures, and more particularly to methods for forming transistors having high-k dielectric layers.

2. Description of the Related Art

With advances in electronic products, semiconductor technology has been applied widely in manufacturing memories, central processing units (CPUs), liquid crystal displays (LCDs), light emitting diodes (LEDs), laser diodes and other devices or chip sets. In order to achieve high-integration and high-speed requirements, dimensions of semiconductor integrated circuits have been reduced and various materials, such as copper and ultra low-k dielectrics, have been proposed and are being used along with techniques for overcoming manufacturing obstacles associated with these materials and requirements. In order to achieve high-speed performance, dimensions of transistors have been shrinking. Also, various gate dielectric materials have been proposed and/or used to provide desired operational speeds of transistors and to prevent gate leakage currents.

FIG. 1 is a schematic drawing showing a traditional gate structure.

Referring to FIG. 1, a gate dielectric layer 110 is formed over substrate 100. A gate layer 120 is formed over the gate dielectric layer 110. Generally, the gate dielectric layer 110 is an oxide layer which has a dielectric constant of about 3.9. As the technology for manufacturing semiconductor devices advances to sub-micron or deep sub-micron scales, the thickness of the gate dielectric layer 110 is reduced. If the gate dielectric layer 110 is thin and a voltage is applied to the thin gate dielectric layer 110, the gate dielectric layer 110 may not withstand such a voltage and may break down, providing leakage paths for the voltage crossing the gate dielectric layer 110. In order to prevent the break-down of the gate dielectric layer 110, a thick gate dielectric layer 110 is desired. However, a thick oxide layer reduces operational speeds of the transistor.

Based on the foregoing, methods and structures for forming high-speed transistors having high-k dielectric layers sufficiently thick so as to prevent breakdown, are desired.

### SUMMARY OF THE INVENTION

In accordance with some exemplary embodiments, a method for forming a semiconductor structure includes forming a gate dielectric layer over a substrate. A top surface of the gate dielectric layer is treated so as to at least partially nitridize the gate dielectric layer. The treated gate dielectric layer is thermally treated with an oxygen-containing precursor such that the at least partially nitridized gate dielectric layer has a nitrogen concentration between about 0.5 atomic percentage (at. %) and about 20 at. %.

In accordance with some exemplary embodiments, a semiconductor structure comprises a nitridized gate dielectric layer formed over a substrate. A gate layer is disposed over the nitridized gate dielectric layer, wherein the nitridized gate dielectric layer has a nitrogen distribution profile, and a peak of the nitrogen distribution profile is above about the middle of the nitridized gate dielectric layer, i.e., the peak profile is between about the middle of the nitridized gate dielectric and an interface between the nitridized gate dielectric layer and the gate layer.

The above and other features will be better understood from the following detailed description of the preferred embodiments of the invention that is provided in connection with the accompanying drawings.

### BRIEF DESCRIPTION OF THE DRAWINGS

Following are brief descriptions of exemplary drawings. They are mere exemplary embodiments and the scope of the present invention should not be limited thereto.

FIG. 1 is a schematic drawing showing a traditional gate structure according to the prior art.

FIGS. 2A-2J are schematic cross-sectional views showing an exemplary method for forming an exemplary transistor.

FIG. 3A graphically illustrates nitrogen distribution profiles within a gate dielectric layer after a thermal treatment with and without an oxygen-containing precursor.

FIG. 3B graphically illustrates relationships between negative-bias temperature instability (NBTI), annealing temperature and annealing time.

FIG. 3C graphically illustrates relationships between chip yields (CP_N), annealing temperature and minimum voltages (Vmin) for sustaining charge storage in complementary metal-oxide-semiconductor (CMOS) device.

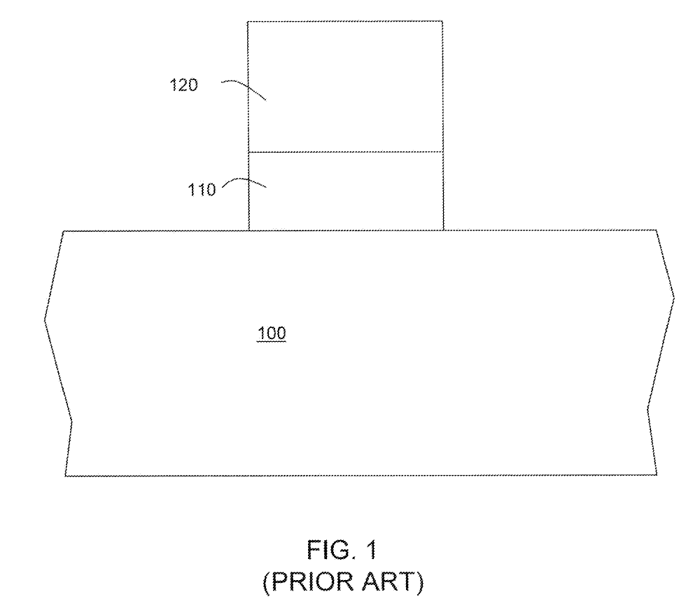

### DETAILED DESCRIPTION OF EXEMPLARY EMBODIMENTS

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus/device be constructed or operated in a particular orientation.

One aspect of exemplary embodiments provides a thick dielectric layer as well as a high-speed transistor. The dielectric layer may have a dielectric constant higher than that of an oxide layer. A silicon nitride layer has a dielectric constant of about 7.5, for example. Attributed to its high dielectric constant, a silicon nitride gate dielectric layer which has a desired thickness for preventing the break-down of the gate dielectric layer may advantageously provide desired dielectric characteristics suitable for high-speed operation of a transistor.

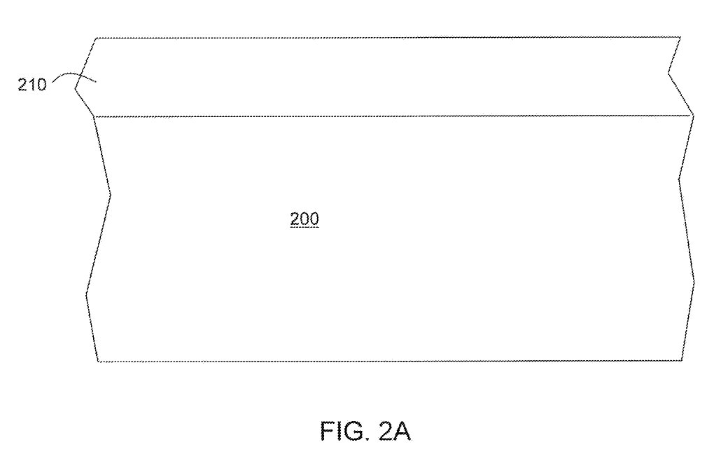

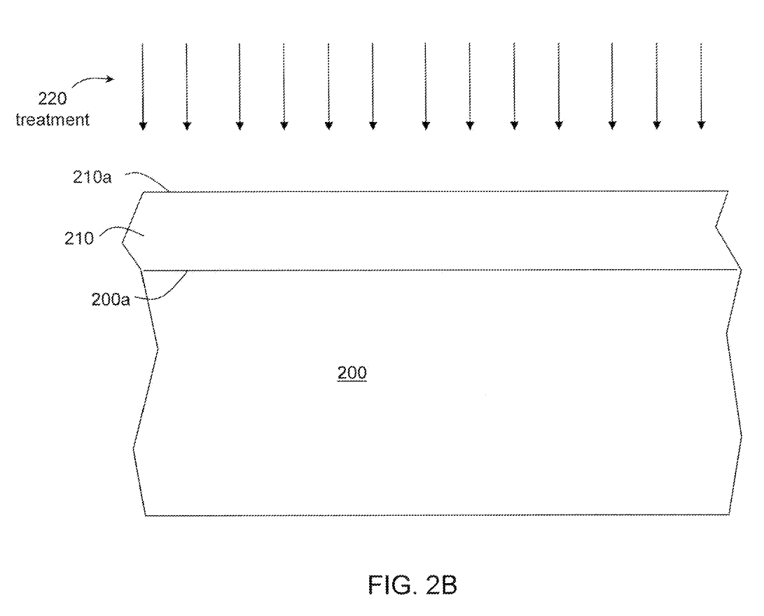

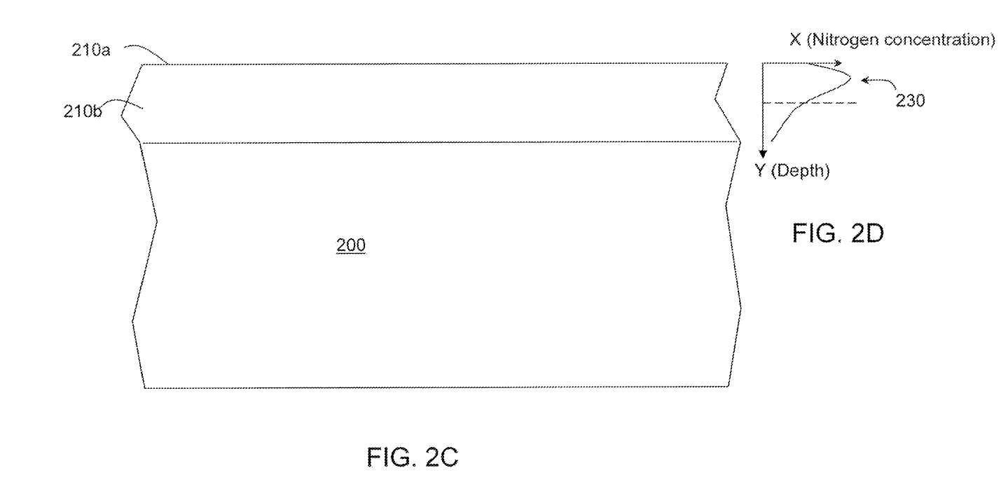

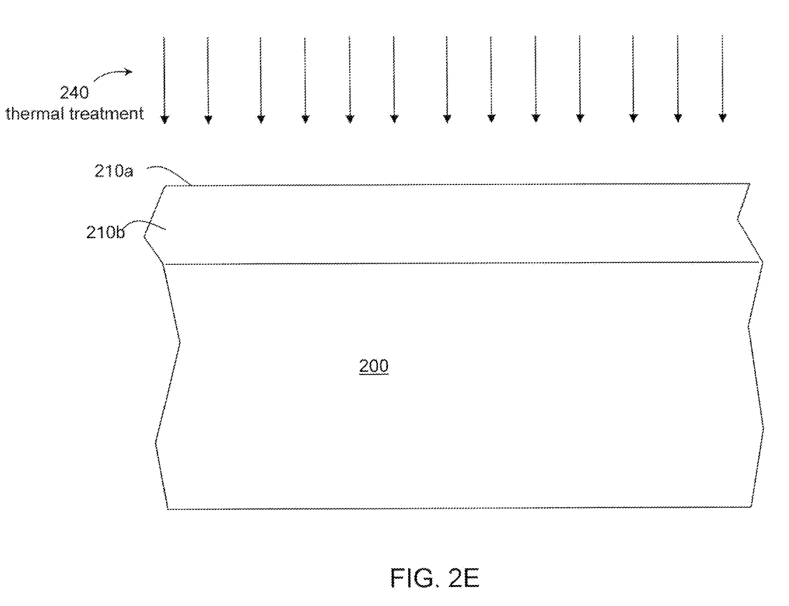

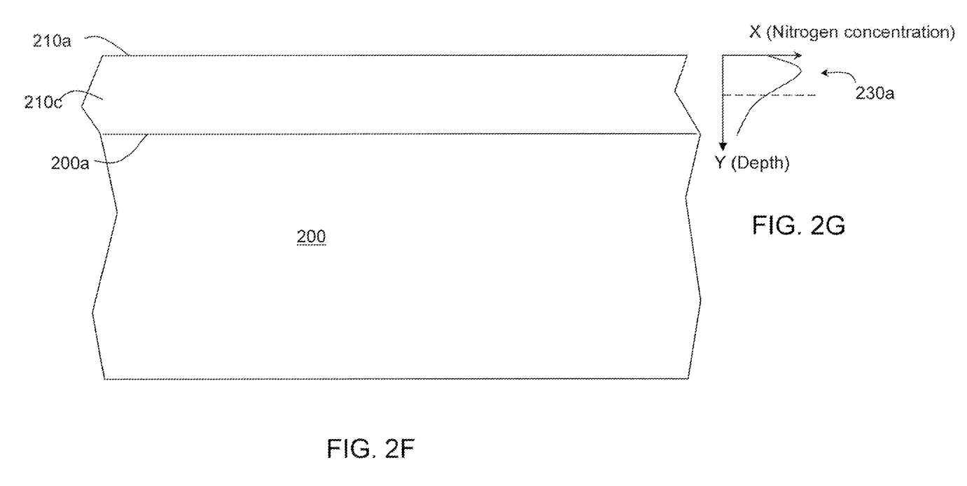

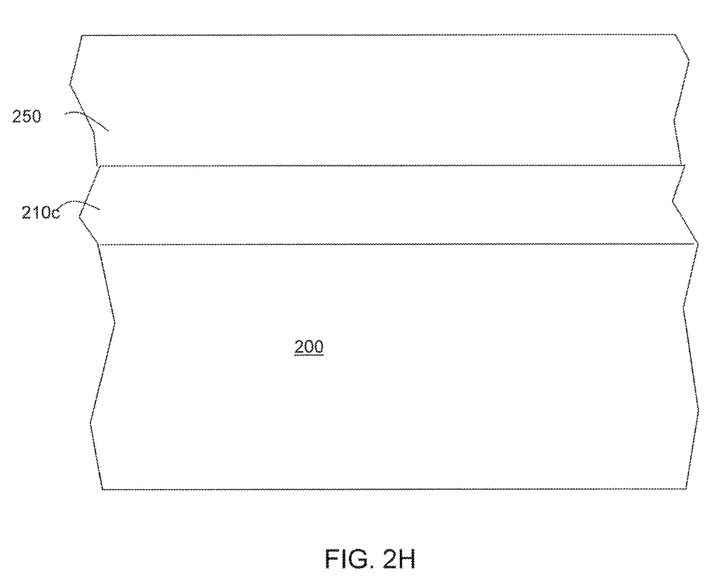

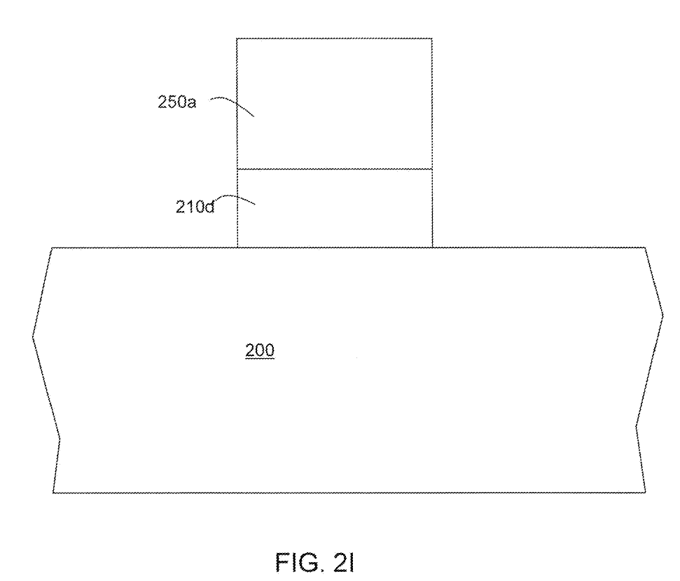

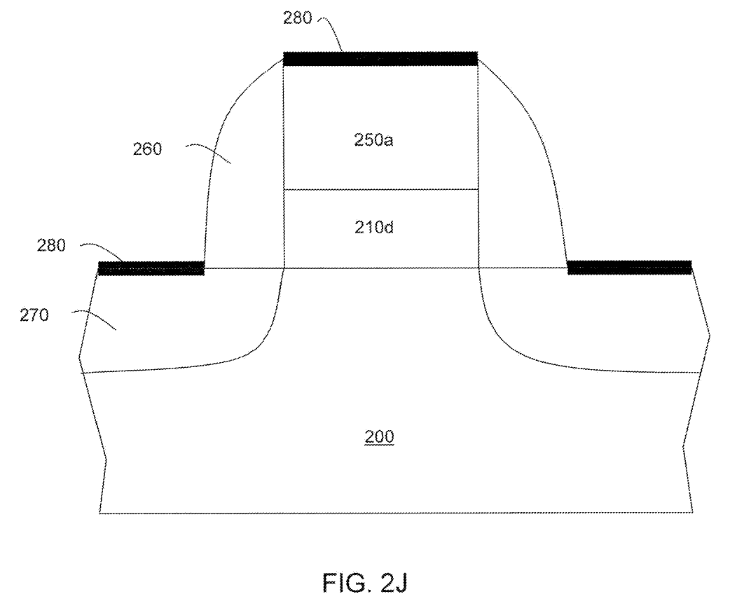

FIGS. 2A-2J are schematic cross-sectional views showing an exemplary method for forming an exemplary transistor.

Referring to FIG. 2A, a gate dielectric layer 210 is formed over a substrate 200. The substrate 200 can be a silicon substrate, a III-V compound substrate, a silicon/germanium (SiGe) substrate, a silicon-on-insulator (SOI) substrate, a display substrate such as a liquid crystal display (LCD), a plasma display, an electro luminescence (EL) lamp display, or a light emitting diode (LED) substrate, for example.

The gate dielectric layer 210 may be, for example, a silicon oxide layer, a silicon nitride layer, a silicon oxynitride layer, a high-k dielectric layer containing a material such as HfO₂, HfSiO₄, ZrO₂, ZrSiO₄, Ta₂O₅, HfSiON or the like, a multiple-layer structure or various combinations thereof. In one exemplary embodiment, the gate dielectric layer 210 may be an oxide layer that is substantially free of nitrogen. In some embodiments, the gate dielectric layer 210 may be formed by, for example, a thermal oxidation process, a chemical vapor deposition (CVD) process, an epitaxy process, other suitable processes, or various combinations thereof. In some embodiments using 65-nm technology, the gate dielectric layer 210 may have a thickness between about 12 Å and about 22 Å. For example, a 65-nm low-power transistor may have a thickness of the gate dielectric layer 210 of about 22 Å; a 65-nm general transistor may have a thickness of the gate dielectric layer 210 of about 16.3 Å; and a 65-nm high-speed transistor may have a thickness of the gate dielectric layer 210 of about 12.3 Å. The thickness of the gate dielectric layer 210, however, is not limited thereto. The thickness of the gate dielectric layer 210 may vary with the technology used for forming a desired transistor.

In some embodiments, the process may use oxygen (O₂) as a precursor for forming the gate dielectric layer 210. The amount of the oxygen provided in the process may be between about 1 liter and about 15 liters, preferably 9 liters. The processing temperature for forming the gate dielectric layer 210 may be, for example, between about 800° C. and about 1050° C. In one embodiment, the processing temperature may be about 975° C. The process for forming the gate dielectric layer 210 may have a processing pressure between about 5 torrs and about 25 torrs in various exemplary embodiments. In one embodiment, the processing pressure may be about 15 torrs. The process for forming the gate dielectric layer 210 may have a processing time between about 5 seconds and about 60 seconds in various exemplary embodiments. In one embodiment, the processing time may be about 24 seconds. Also, the conditions for forming the gate dielectric layer 210 may vary with desired thicknesses and qualities of the gate dielectric layer 210.

Referring to FIG. 2B, the surface 210a of the gate dielectric layer 210 is subjected to a treatment 220 represented by the arrows so as to form a nitridized gate dielectric layer 210b shown in FIG. 2C. The treatment 220 may comprise, for example, a plasma treatment, an ion-implantation treatment, or the like or various combinations thereof. In some embodiments, the treatment 220 may use a precursor having a nitrogen-containing gas such as nitrogen (N₂), nitrogen dioxide (NO₂), nitrous oxide (N₂O), ammonia (NH₃), or the like or various combinations thereof.

In some embodiments using a plasma treatment, the treatment 220 may have an amount of nitrogen between about 0.1 liter and about 5 liters, preferably about 1.1 liters; a processing temperature between about room temperature and 125° C., preferably at about room temperature; a processing pressure between about 1 milli-torr (mTorr) and about 30 mTorrs, for example about 20 mTorrs; a radio-frequency (RF) power between about 200 watts and about 3,500 watts, for example about 1,500 watts; a RF frequency between about 1,000 Hz and about 50,000 Hz, for example about 10,000 Hz; and a processing time between about 10 seconds and about 300 seconds, for example about 100 seconds.

Referring to FIG. 2C, the nitridized gate dielectric layer 210b is formed. In some embodiments, the nitridized gate dielectric layer 210b may have a nitrogen distribution profile 230 as shown in FIG. 2D. The nitrogen distribution profile 230 may have a peak (not labeled) between about the middle of the nitridized gate dielectric layer 210b and the top surface 210a of the nitridized gate dielectric layer 210b. In other embodiments, the peak of the nitrogen distribution profile 230 falls at other locations within the nitridized gate dielectric layer 210b. In still other embodiments, the peak nitrogen concentration may lie at the interface 200a between the nitridized gate dielectric layer 210b and the substrate 200. The peak nitrogen concentration may include a concentration between about 0.5 atomic percentage (at. %) and about 20% at. %, preferably between about 8.0 at. % and about 8.5 at. %, such that a leakage current induced by the nitrogen component at the interface 200a is desired.

Referring to FIG. 2E, the nitridized gate dielectric layer 210b is subjected to a thermal treatment 240 represented by the arrows with an oxygen-containing precursor. The thermal treatment 240 may be performed by, for example, a furnace, a CVD apparatus, a rapid thermal annealing (RTA) apparatus, or the like, or various combinations thereof. The oxygen-containing precursor may be, for example, oxygen. In some embodiments, the oxygen-containing precursor may comprise a nitrogen-containing gas and/or an inert gas (e.g., helium, neon, argon or xenon) mixed therein. The nitrogen-containing gas may be, for example, nitrogen (N₂), nitrogen dioxide (NO₂), nitrous oxide (N₂O), ammonia (NH₃), or the like or various suitable combinations thereof. In some embodiments using a mixture of nitrogen and oxygen, the thermal treatment 240 may have an amount of nitrogen between about 0.01 liter and about 30 liters, preferably 20 liters; an amount of oxygen between about 0.05 liter and about 0.25 liter, preferably 0.15 liter; a processing temperature between about 900° C. and about 1080° C., for example about 1050° C. in one exemplary embodiment; a processing pressure between about 1 torr and about 5 torrs, for example 3 torrs in one exemplary embodiment; and a process time about 20 seconds or more, for example about 70 seconds in one exemplary embodiment. In some embodiments using 65-nm to 90-nm technology, the process time may be about 70 seconds or more. In other embodiments using 45-nm to 55-nm technology, the process time may be about 90 seconds or more. In still other embodiments using 22-nm to 45-nm technology, the process time may be about 120 seconds or more. In some embodiments, a percentage of the oxygen is about 0.1% by volume or more. The conditions of the thermal treatment 240, however, are not limited thereto and may vary with the technology used for forming a transistor with various desired performance characteristics.

Referring to FIG. 2F, the gate dielectric layer 210c is formed after the thermal treatment 240 shown in FIG. 2E. After the thermal treatment 240, nitrogen may diffuse toward the interface between the gate dielectric layer 210c and the substrate 200. In some embodiments, the nitrogen distribution profile 230a shown in FIG. 2G may have a peak lower than that of the nitrogen distribution profile 230 shown in FIG. 2D. The nitrogen distribution profile 230a may have a peak (not labeled) between about the middle of the gate dielectric layer 210c and the top surface 210a of the gate dielectric layer 210c. In other embodiments, the peak of the nitrogen distribution profile 230a may fall at other locations within the gate dielectric layer 210c. In still other embodiments, the nitrogen concentration at the interface 200a between the gate dielectric layer 210c and the substrate 200 may be between about 0.5 at. % and about 20 at. %, preferably between about 8 at. % and about 8.5 at. %, such that a leakage current induced by the nitrogen component at the interface 200a is desired.

Referring to FIG. 2H, a gate material layer 250 is formed over the gate dielectric layer 210c. The gate material layer 250 may be, for example, a silicon layer, a polysilicon layer, an amorphous silicon layer, a SiGe layer, a conductive material layer, other suitable layers, or the combinations thereof. The gate material layer 250 may be formed by, for example, a CVD process but other suitable formation processes may alternatively be used. The gate material layer 250 is provided to form a gate layer 250a (shown in FIG. 2H).

Referring to FIG. 2I, a patterned gate layer 250a and a gate dielectric layer 210d are formed over the substrate 200 by patterning the gate layer 250 and the gate dielectric layer 210c shown in FIG. 2H. The patterning process may include forming a photoresist pattern (not shown) over the gate material layer 250 shown in FIG. 2H. An etch process then partially removes the gate material layer 250 and the gate dielectric layer 210c using the patterned photoresist layer as a mask layer. After the etch process, the patterned photoresist layer may be removed by a photoresist removal process to produce the structure shown in FIG. 2I.

Referring to FIG. 2J, spacers 260 are formed on sidewalls (not labeled) of the gate layer 250a and the gate dielectric layer 210d. The spacers 260 may comprise a material such as oxide, nitride, oxynitride, or the like or various combinations thereof. The spacers 260 can be formed by, for example, using a CVD process to form a dielectric layer (not shown) substantially conformal over the structure shown in FIG. 2I. The dielectric layer (not shown) may be then subjected to an anisotropic etch process which partially removes the dielectric layer (not shown) so as to the form the spacers 260.

Referring again to FIG. 2J, source/drain (S/D) regions 270 are formed within the substrate 200 and may be adjacent to the spacers 260 or the gate structure, i.e., dielectric layer 210d as illustrated. The S/D regions 270 can be formed by, for example, an implantation process with arsenic (As), phosphorous (P), boron (B) or other dopants. In some embodiments, the S/D regions 270 may contain a material such as germanium (Ge), carbon (C), or the like, or combinations thereof. The implantation process uses the spacers 260 and the gate layer 250a as a mask layer. Various techniques may be used to form the S/D regions 270 to a desired depth within the substrate 200.

Still referring to FIG. 2J, silicide layers 280 may be formed at the top surface of the gate layer 250a and the exposed, top surfaces of the S/D regions 270. The silicide layers 280 may be a material such as tungsten silicide, cobalt silicide, titanium silicide, molybdenum silicide, or the like, or various combinations thereof. The silicide layers 280 can be formed by, for example, a CVD process or a physical vapor deposition (PVD) process.

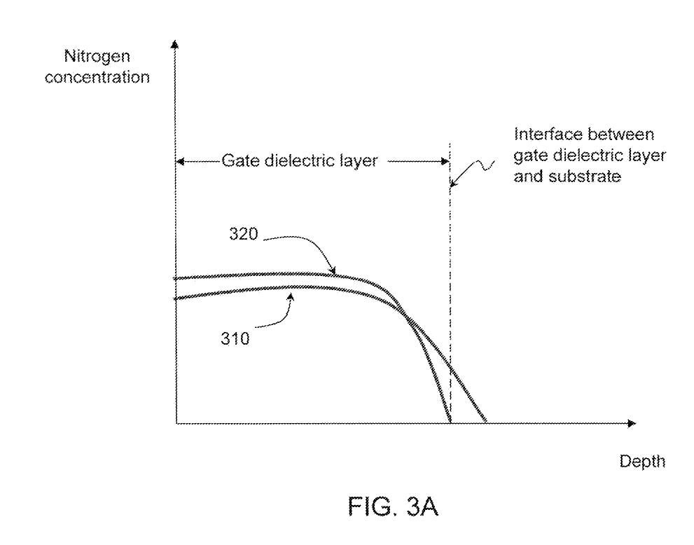

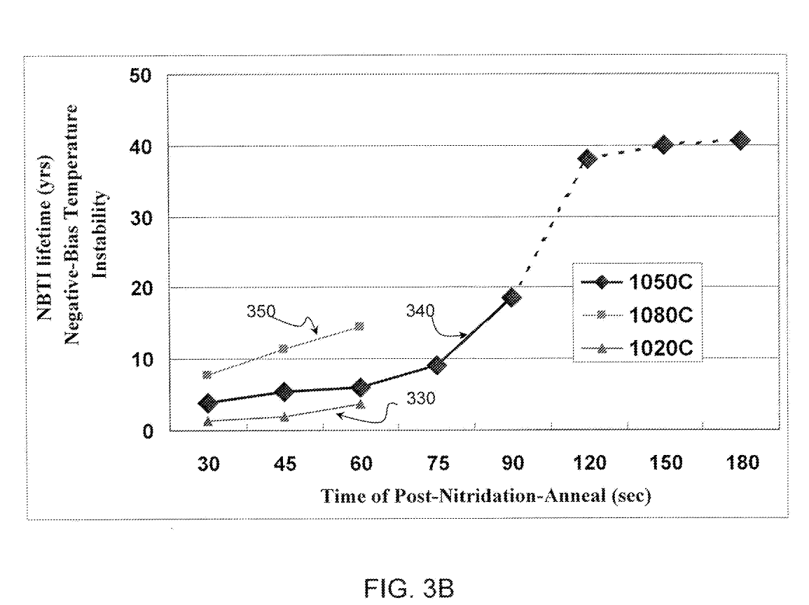

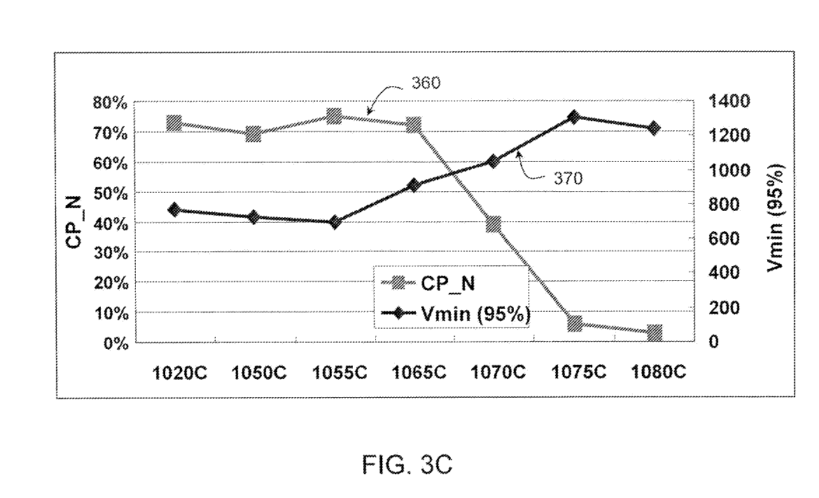

FIG. 3A is a schematic drawing showing nitrogen distribution profiles within a gate dielectric layer after a thermal treatment with and without an oxygen-containing precursor.

Referring to FIG. 3A, the nitrogen distribution profile 310 represents the dopant profile after annealing process, i.e., treatment 240 using pure nitrogen, and the nitrogen distribution profile 320 represents the dopant profile after annealing process i.e., the treatment 240 using a mixture of nitrogen and oxygen. In each case, the annealing process treatment 240 follows the nitridation process 220. It is found that the nitrogen concentration of the profile 310 extends over the interface between the gate dielectric layer and the substrate. The profile 320, at the interface between the gate dielectric layer and substrate and/or within the substrate, has nitrogen concentration which is lower than that of the profile 310. It is also found that nitrogen existing at the interface between of the gate dielectric layer and the gate layer and/or beneath the interface may provide a leakage current path, inducing leakage currents. The thermal treatment within an oxygen-containing ambient after the gate dielectric nitridation process (i.e., treatment 220) may desirably reduce the nitrogen concentration level at the interface between the gate dielectric layer and the substrate and/or beneath the interface. It is found that the reduced level of the nitrogen at and/or beneath the interface may be attributed to the diffusion of oxygen to the interface and oxygen at the interface may curb the diffusion of nitrogen.

FIG. 3B is a schematic drawing showing relationships between negative-bias temperature instability (NBTI), annealing temperature and annealing time.

Referring to FIG. 3B, curve 330 represents the annealing process with a temperature of about 1020° C.; curve 340 represents the annealing process with a temperature of about 1050° C.; and curve 350 represents the annealing process with a temperature of about 1080° C. The solid lines represent experimental data and the dashed line represents theoretical predictions. All of the annealing processes illustrated in FIG. 2B are performed within an ambient containing an oxygen-containing precursor such as a mixture of nitrogen and oxygen after the nitridation of the gate dielectric layer (i.e., treatment 220 shown in FIG. 2B). It is found that the NBTI is improved when the annealing temperature and/or annealing time are increased. In some embodiments, the improvement of NBTI may gradually saturate after an annealing time such as about 120 seconds or more as indicated by curve 340 shown in FIG. 3B.

FIG. 3C is a schematic drawing showing relationships between chip yields (CP_N), annealing temperature and minimum voltages (Vmin) for sustaining charge storage in complementary metal-oxide-semiconductor (CMOS) device.

Referring to FIG. 3C, curve 360 represents a relationship between chip yield (CP_N) and annealing temperature, and curve 370 represents a relationship between Vmin and annealing temperature. All of the annealing processes are performed within an ambient containing an oxygen-containing precursor such as a mixture of nitrogen and oxygen after the nitridation of the gate dielectric layer (i.e., treatment 220 shown in FIG. 2B). It is found that the chip yield starts declining when the annealing temperature is about 1065° C. or more. The chip yield may gradually saturate at about 1075° C. or more. It is believed that the decline of the chip yield may result from gate oxide leakage currents. Also, it is noticed that the Vmin starts increasing between about 1055° C. and about 1065° C. The increase of the Vmin may gradually saturate at about 1075° C. or more. The increase of the Vmin may result from gate oxide leakage currents.

Although the present invention has been described in terms of exemplary embodiments, it is not limited thereto. Rather, the appended claims should be construed broadly to include other variants and embodiments of the invention which may be made by those skilled in the field of this art without departing from the scope and range of equivalents of the invention.

What is claimed is:

1. A method for forming a semiconductor structure, comprising:
forming a gate dielectric layer over a substrate;
treating a top surface of the gate dielectric layer so as to at least partially nitridize the gate dielectric layer; and
thermally treating the treated gate dielectric layer with an oxygen-containing precursor such that the at least partially nitridized gate dielectric layer has a nitrogen concentration between about 0.5 atomic percentage (at. %) and about 20 at. %.

2. The method of claim 1, wherein said forming a gate dielectric layer comprises forming an oxide layer substantially free of nitrogen.

3. The method of claim 1, wherein said treating a top surface of the gate dielectric layer comprises plasma treating the top surface of the gate dielectric layer with a nitrogen-containing precursor.

4. The method of claim 1, wherein said of thermally treating the treated gate dielectric layer comprises annealing the treated gate dielectric layer.

5. The method of claim 4, wherein the oxygen-containing precursor comprises nitrogen (N₂) and oxygen (O₂).

6. The method of claim 5, wherein the nitrogen is present in an amount ranging from about 0.01 liter to about 30 liters and the oxygen is present in an amount ranging from about 0.05 liters to about 0.25 liters.

7. The method of claim 4, wherein a percentage of the oxygen is about 0.1% by volume or more.

8. The method of claim 1, wherein said thermally treating the treated gate dielectric layer has a processing time of about 20 seconds or more and a processing temperature between about 900° C. and about 1080° C.

9. The method of claim 1 further comprising:
forming a gate layer over the thermally treated gate dielectric layer; and
patterning the gate layer and the thermally treated gate dielectric layer thereby forming a gate structure of a transistor.

10. The method of claim 1, wherein the at least partially nitridized gate dielectric layer has a nitrogen concentration between about 8 atomic percentage (at. %) and about 8.5 at. %.

11. A method for forming a semiconductor structure, comprising:
forming a gate dielectric layer over a substrate;
plasma treating a top surface of the gate dielectric layer with a first precursor including a first nitrogen-containing gas so as to at least partially nitridize the gate dielectric layer; and
annealing the plasma treated gate dielectric layer with a second precursor comprising a second nitrogen-containing gas and an oxygen-containing gas such that the at least partially nitridized gate dielectric layer has a nitrogen concentration between about 0.5 atomic percentage (at. %) and about 20 at. %.

12. The method of claim 11, wherein said forming a gate dielectric layer comprises forming an oxide layer substantially free of nitrogen.

13. The method of claim 11, wherein the second nitrogen-containing gas comprises nitrogen (N₂) and the oxygen-containing gas comprises oxygen (O₂).

14. The method of claim 13, wherein the second precursor includes the nitrogen in an amount between about 0.01 liter and about 30 liters and the oxygen in an amount between about 0.05 liters and about 0.25 liters.

15. The method of claim 13, wherein a percentage of the oxygen is about 0.1% by volume or more in the second precursor.

16. The method of claim 11, wherein said annealing the plasma treated gate dielectric layer has a processing time of about 20 seconds or more and a processing temperature between about 900° C. and about 1080° C.

17. The method of claim 11 further comprising:
forming a gate layer over the annealed gate dielectric layer; and
patterning the gate layer and the annealed gate dielectric layer thereby forming a gate structure of a transistor.

18. The method of claim 11, wherein the at least partially nitridized gate dielectric layer has a nitrogen concentration between about 8 atomic percentage (at. %) and about 8.5 at %.
